(19) United States
(12) Patent Application Publication
(10) Pub. No.: US 2007/0131162 A1
(43) Pub. Date: Jun. 14, 2007

(54) Single crystal growing apparatus

(75) Inventors: Hiroshi Nishimura, Shiga (JP); Toru Nagasawa, Shiga (JP); Ryusuke Iwasaki, Shiga (JP); Shinichi Ikeda, Ibaraki (JP); Naoki Shirakawa, Ibaraki (JP); Hiroshi Eisaki, Ibaraki (JP); Norio Umeyama, Ibaraki (JP); Yoshiyuki Yoshida, Ibaraki (JP); Ichirou Nagai, Ibaraki (JP); Shigeo Hara, Ibaraki (JP)

Correspondence Address: OBLON, SPIVAK, MCCLELLAND, MAIER & NEUSTADT, P.C., 1940 DUKE STREET, ALEXANDRIA, VA, 22314, US

(73) Assignees: Nec Machinery Corporation, Shiga (JP); National Inst of Adv. Industrial Sci. and Tech, Tokyo (JP)

(21) Appl. No.: 10/588,510

(22) PCT Filed: Feb. 4, 2005
(86) PCT No.: PCT/JP05/01725

§ 371 Date: Aug. 4, 2006

(30) Foreign Application Priority Data
Feb. 5, 2004 (JP) 2004-029424

(51) Int. Cl. C30B 15/00; C30B 27/02; C30B 11/00

(52) U.S. Cl. 117/204; 117/217

(57) ABSTRACT

The object of the present invention is to provide a compact and inexpensive single-crystal growth apparatus. The single-crystal growth apparatus of the present invention which comprises spheroid mirrors 11, 12, heat sources 13, 14 located at the one foci F₁, F₂ of the spheroid mirrors 11, 12, a quartz tube 16 enclosing a heating zone 15 of the common focus F₀ on the other side, and, in the quartz tube 16, a feed rod 18 supported by an upper crystal drive shaft 17 and a seed crystal rod 20 supported by a lower crystal drive shaft 19. The interfocal distance between the foci F₁, F₂ and the foci F₀ is made 41.4-67.0 mm and the minor axis/major axis ratio of the spheroid mirrors is set to 0.90-0.95. In order to prevent excessive heat rise of the spheroid mirrors 11, 12 and infrared lamps 13, 14 attendant on downsizing of the spheroid mirrors 11, 12, the spheroid mirrors 11, 12 internally include annular water-cooling jackets 39, 40 and air-cooling units 45a, 46a are provided for introducing cooling air from gaps 43, 44 of the spheroid mirrors 11, 12 at a flow rate of 1.2-2.3 m³/min. Further, ease of use is realized by self-circulating cooling water and imputing heat dissipation capacity utilizing a radiator 49.

### TECHNICAL FIELD

This invention relates to a single-crystal growth apparatus, particularly to a single-crystal growth apparatus that is an apparatus for growing single crystal by a floating zone melting method of the infrared-ray concentrated heating-type, which is of reduced size and wherein excessive temperature rise of spheroid mirrors is prevented.

### BACKGROUND ART

It is known to use a floating zone-type single-crystal growth apparatus in the case of growing a single crystal (see Patent Reference 1).

An example of the floating zone-type single-crystal growth apparatus is shown in FIG, 15. FIG. 15 is a longitudinal sectional view seen from the front of a single-crystal growth apparatus 60 of the bi-spheroid type that uses a halogen lamp as a heat source; FIG. 16 is a cross-sectional view along line A-A in FIG. 15; and FIG. 17 is an enlarged front view of a heating zone.

The single-crystal growth apparatus 60 has two symmetrically shaped spheroid mirrors 61, 62 joined to face each other so that the one foci F₀, F₀, thereof coincide, thereby configuring a heating furnace. The inner surfaces, i.e., the reflecting surfaces, of the spheroid mirrors 61, 62 are gold plated so as to reflect infrared rays at high reflectance. Heat sources, c.g., halogen lamps or other type of infrared lamps 63, 64, are fixedly mounted near the other foci F₁, F₂ of the spheroid mirrors 61, 62. A heating zone 65 is located at the coincident foci F₀ of the spheroid mirrors 61, 62, at which a feed rod 67 fixed to the lower end of an upper crystal drive shaft 66 extending vertically from above and a seed crystal rod 69 fixed to the upper end of a lower crystal drive shaft 68 extending vertically from below are abutted. As illustrated, the upper crystal drive shaft 66 and lower crystal drive shaft 68 are airtightly retained by retaining members 70, 71 to be rotatable by unshown servomotors or other such drive motors, and retained to be movable vertically either synchronously or so as to have a relative velocity.

The space m₁ in which the feed rod 67 and seed crystal rod 69 are located is partitioned off from the space m₂ in which the infrared lamps 63, 64 are located, a transparent quartz tube 73 is provided to form a single-crystal growth chamber 72 and the single-crystal growth chamber 72 is charged with an inert gas or the like favorable for crystal growth, while the infrared lamps 63, 64 are air cooled for lighting them safely.

Thus, within the spheroid mirrors 61, 62, the space m₁ defined by the quartz tube 73 is made to serve as the single-crystal growth chamber 72, whereby the volume of the single-crystal growth chamber 72 becomes markedly smaller than in the case where, without providing the quartz tube 73, the entire heating furnace constituted by the spheroid mirrors 61, 62 is made to serve as the single-crystal growth chamber, and, therefore, the atmosphere in the single-crystal growth chamber 72 can be converted to a prescribed single-crystal growth atmosphere in a short period of time and that atmosphere state can be easily maintained.

In the single-crystal growth apparatus 60, infrared rays radiated from the infrared lamps 63, 64 located at the first and second foci F₁, F₂ of the spheroid mirrors 61, 62 is reflected by the spheroid mirrors 61, 62 to be focused at the heating zone 65 located at the common focus F₀ to perform infrared-ray heating. While being heated and melted by the radiant energy produced by the infrared heating, the lower end of the feed rod 67 and the upper end of the seed crystal rod 69, present at the heating zone 65, are smoothly brought into contact so that, as shown in FIG. 17, a floating zone 74 is formed at the heating zone 65 between the feed rod 67 and seed crystal rod 69.

Then the upper crystal drive shaft 66 having the feed rod 67 fastened to its lower end and the lower crystal drive shaft 68 having the seed crystal rod 69 fastened to its upper end are both rotated and are also slowly moved downward synchronously or so as to have a relative velocity, whereby the floating zone 74 between the feed rod 67 and seed crystal rod 69 gradually moves toward the feed rod 67 side and crystal grows to produce a single-crystal. In FIG. 17, 67a designates the solid-liquid interface on the feed rod 67 side and 69a designates the solid-liquid interface on the seed crystal rod 69 side.

When this floating zone-type single-crystal growth apparatus 60 is used, the infrared rays radiated by the halogen lamps or other type of infrared lamps 63, 64 are reflected by the entire surfaces of the spheroid mirrors 61, 62 to be focused at the heating zone 65 located at the common focus F₀, thereby performing infrared-ray heating, so it is possible not only to heat the heating zone 65 to a high temperature by small infrared lamps 63, 64 of relatively low output but also to control the temperature of the heating zone 65 easily and reliably by controlling the power input to the infrared lamps 63, 64.

Moreover, the fact that the single crystal can be grown in a floating state without the melt of the feed rod 67 and seed crystal rod 69 contacting other substances makes it possible to readily grow high-purity single crystal, because, unlike in crucible-type single crystal growth, the purity of the grown single crystal is not degraded by impurities dissolved out from a crucible.

Patent Reference 1: Japanese Patent Publication No. HEI 5-34317 (column 2, line 7-column 3, line 2; FIG. 1)

### DISCLOSURE OF THE INVENTION

Problems to be Solved by the Invention

The conventional single-crystal growth apparatus 60 ordinarily uses spheroid mirrors 61, 62 whose major axes a=117 mm and minor axes b=108 mm, or thereabout, (minor axis/major axis ratio=0.92; see FIG. 1 regarding major axes a and minor axes b), and when the crystal growth quantity is made 150 mm, the apparatus dimensions become: width W−840 mm, height H=2,180 mm and depth D=1,880 mm, or thereabout; and the cost is also high. It is possible to obtain a single crystal of a diameter of about φ3-15 mm and length of 150 mm.

On the other hand, in the case of developing a new single crystal or growing a known single crystal and investigating its properties, a large single crystal is not always necessary and even a small single crystal may suffice. If anything, demand has increased for an apparatus that reduces development and research costs by enabling simple growth of single crystals. Where there is no desire for large diameter, the need is for a compact, inexpensive apparatus that can perform single crystal growth simply and is capable of growing single crystal having a diameter of, for example, about φ3-10 mm. Although the size of the single-crystal growth apparatus can be reduced by reducing the size of the spheroid mirrors 61, 62 and quartz tube 73, the infrared lamps installed then have to be made smaller. Even in such a configuration, the heating performance must be maintained at a high level.

When the apparatus size was reduced by setting the interfocal distance of the bi-spheroid type spheroid mirrors 61, 62 (in FIG. 1, F₁-F₀=2F) to 50 mm, it was found that for achieving the same heating condition of the heating zone as that in conventional single crystal growth it was sufficient for the output of the infrared lamps to be ½ the conventional value.

However, when the lamp power was set in this manner, the temperature of the spheroid mirrors 61, 62 rose excessively owing to the fact that the reflection surface area of the spheroid mirrors 61, 62 became about ¼, and also owing to the shortening of the distance between the infrared lamps 63, 64 and the spheroid mirrors 61, 62, and the up-flow and convection of retained heat caused by the reduced volume of the space m₂ within the spheroid mirrors 61, 62.

Therefore, unless an effective cooling method is adopted, a new problem arises in that the gold plating layers easily peel off the inner surfaces of the spheroid mirrors 61, 62 owing to the difference in thermal expansion coefficient between the material of the spheroid mirrors 61, 62 (e.g., brass) and the gold plating layers coating the inner surfaces thereof.

In the conventional single-crystal growth apparatus 60, the spheroid mirrors 61, 62 are water-cooled by passing cooling water through jackets of the spheroid mirrors and, further, the infrared lamps 63, 64 located at the first and second foci F₁, F₂ of the spheroid mirrors 61, 62 are air cooled by cooling air passed at a flow rate of about 5-10 liter/min. However, when, as mentioned above, the size of the single-crystal growth apparatus was reduced by making the interfocal distance 50 mm, it was found that peeling of the gold plating layer of the spheroid mirrors 61, 62 could by no means be prevented using such a cooling system.

Specifically, in simulation with respect to maximum allowable total lamp power in the case of setting the interfocal distance of the spheroid mirrors 61, 62 to 50 mm, the maximum allowable total lamp power usable was limited to 400 W in the case of (1) adopting air cooling in which cooling air is passed through jackets of the spheroid mirrors 61, 62 and further passing cooling air for cooling the infrared lamps 63, 64 located at the first and second foci F₁, F₂ of the spheroid mirrors 61, 62 at a flow rate of about 5-10 liter/min.

Moreover, the maximum allowable total lamp power usable was limited to 1,100 W in the case of (2) adopting water cooling for cooling of the spheroid mirrors 61, 62 and further passing cooling air for cooling the infrared lamps 63, 64 located at the first and second foci F₁, F₂ of the spheroid mirrors 61, 62 at a flow rate of about 5-10 liter/min.

At these lamp powers, the temperature reached at the heating zone 65 is lower than 2,0000° C., making it impossible to grow single crystal by, for example, melting ruby (Al₂O₃+1% Cr₂O₃; melting point about 2,060° C.).

The first object of the present invention is to reduce the size of the single-crystal growth apparatus as much as possible and achieve heating performance of 2,000° C. or higher with the smallest possible power, and the second object thereof is, by adopting an effective cooling method, to prevent overheating of the inner surfaces of the spheroid mirrors, thereby preventing peeling of the gold plating layers or other such reflection layers, and to prevent overheating of the heat source surfaces, thereby prolonging the service life thereof.

Means for Solving the Problems:

In a single-crystal growth apparatus which comprises spheroid mirrors, heat sources located at the one foci of the spheroid mirrors, a feed rod and a seed crystal rod located at the other foci of the spheroid mirrors, a quartz tube surrounding the feed rod and seed crystal rod, and shaft drive means for rotating and vertically moving crystal drive shafts respectively supporting the feed rod and seed crystal rod, and in which infrared rays of the heat sources are reflected by the spheroid mirrors to irradiate the feed rod and seed crystal rod located at the other foci, thereby growing single crystal,

the single-crystal growth apparatus of the present invention is, for solving the aforesaid problems, characterized in that the interfocal distance of the one and other foci is made 41.4-67.0 mm and the minor axis/major axis ratio of the spheroid mirrors is made 0.90-0.95 (claim 1).

The interfocal distance is about half that in the conventional apparatus, and it was found by the inventors that the output of the infrared lamps required to achieve the same heating performance is only about one half that heretofore.

Further, in such a compact apparatus, the present invention is characterized in that the major axes a of the spheroid mirrors are set to 57.7-80 mm, the minor axes b to 52-76 mm, and the total power of the heat sources to 1,100-1,500 W, thereby making it possible to achieve heating performance of 2,000° C. (claim 2).

Further, in the compact apparatus, the present invention is characterized in that the spheroid mirrors are of the bi-spheroid type and the total power of the heat sources is set to 1,100-1,500 W, thereby making it possible to achieve heating performance of 2,000° C. (claim 3).

Further, the present invention is characterized in that the spheroid mirrors include internal water-cooling jackets, the ends of the spheroid mirrors in the major axis direction are formed with heat source insertion holes for inserting the heat sources into inner space of the spheroid mirrors, and air-cooling units are provided for introducing cooling gas for cooling the spheroid mirrors and heat sources from gap regions inward of the heat source insertion holes into the inner space of the spheroid mirrors at a flow rate of 1.2-2.3 m³/min (claim 4).

Conventionally, the cooling air flow rate has been around 10 liters at the most, so that the flow rate of the apparatus of the present invention is 120 times-230 times that of the prior art which will be understood to be a tremendous flow rate. The conventional single-crystal growth apparatus consumes more than twice as much electric power as the apparatus of the present invention but gets by with no more than around 10 liters of cooling air. Since the apparatus of the present invention requires only about half as much power as heretofore, it would, by ordinary thinking, be logical to conclude that a proportionally smaller amount of cooling air would suffice. But in the apparatus of the present invention, the downsizing of the spheroid mirrors improves the heating efficiency even though low-power heat sources are used, so that the heating performance of the conventional apparatus (target of 2,000° C.) can be maintained, Owing to the fact that the downsized apparatus maintains the heating performance of the conventional apparatus, however, the flow rate of the cooling air has to be dramatically increased over the conventional level. Thus, the novelty of the present invention can be said to lie in the discovery of the relationship between smaller apparatus size and higher heating efficiency, and the finding of a solution to the cooling problem that was indispensable to realizing such an apparatus.

In addition, owing to the positioning of the heat source insertion holes at both ends of the spheroid mirrors of bi-spheroid type, the cooling gas first cools the heat source surfaces and then flows along the opposite surfaces to cool the reflection surfaces, and part of the cooling gas is blown directly onto the quartz tube to cool it evenly from both the left and right sides.

When the inner diameter of the quartz tube decreases owing to downsizing of the single-crystal growth apparatus, the temperature of the quartz tube readily increases owing to secondary radiation from the heated melt and the fact that vaporized material adhering to the quartz tube absorbs light. Since the quartz tube tends to turn cloudy upon reaching a high temperature of 600-700° C., it must always be cooled to or below 500° C. Once this cloudiness occurs, light is prevented from reaching the material because it is absorbed by the cloudy portion, and since the temperature of the melt zone inside the quartz tube does not rise as desired and the melt zone is no longer heated evenly in the circumferential direction, good single crystal growth is inhibited. In addition, the cloudy quartz tube cannot be reused. In the present invention, the opposite sides of the quartz tube are cooled symmetrically, so that no local high-temperature regions occur, whereby clouding of the quartz tube can be reliably prevented even when the apparatus is downsized. It is worth noting that in experiments, partial clouding of the quartz tube was observed in the case where, differently from in the present invention, cooling gas was not blown from heat source insertion holes formed at the opposite ends of the spheroid mirrors of bi-spheroid type, i.e., when cooling gas was blown in from portions other than the heat source insertion holes, even when the cooling gas was blown in at the same flow rate as in the present invention.

Further, the following merits appear when a configuration is adopted that makes the total power consumption of the electrical system including the heat sources 1,500 W or less, That is to say, utilization in Japan becomes possible at 100 V, 15 A, so that the single-crystal growth apparatus can be readily installed at research facilities, educational facilities and the like which have not contracted for high-wattage power supply exceeding 200 V or 15 A. Use is similarly possible overseas within the range of the commercial line voltage and current-carrying capacity of ordinary households. For example, Japanese domestic specifications can be easily used in the United States within the range of 208 V, 20 A and in France within the range of 200 V and 20 A, by using a transformer to convert the input power from 208 V and 200 V to 100 V.

Further, the single-crystal growth apparatus of the present invention is characterized in that it is configured so that the flow of the cooling gas introduced into the spheroid mirrors from the air-cooling units becomes turbulent in the inner space of the spheroid mirrors to cool the inner surfaces of the spheroid mirrors and the heat sources located in the inner space of the spheroid mirrors (claim 6).

By adopting this configuration, air elevated to a high temperature that resides or circulates in the spaces within the spheroid mirrors can be forcibly discharged to efficiently cool the spheroid mirrors and the heat sources.

Further, the single-crystal growth apparatus of the present invention is characterized in that it comprises a cooling water self-circulation-type heat exhaust system that has a path through which cooling water supplied to the water cooling jackets of the spheroid mirrors circulates via a radiator and dissipates the temperature of the cooling water by supplying cooling air to the radiator (claim 7).

The single-crystal growth apparatus of this invention enables spheroid mirror cooling with only a simple circulation-type heat exhaust system because it enables reduced heat source power consumption. Specifically, unlike conventional apparatuses, which have an expensive circulator installed outside the apparatus, the present invention does not require cooling water supply piping or drainage piping, so that installation is simple, cooling water supply pipes and discharge pipes do not become a hindrance during inspection and maintenance, and the apparatus can be easily moved when changes in layout etc. are made after installation.

When the interfocal distance of the spheroid mirrors is less than 41.4 mm, single crystal growth becomes impossible because the spheroid mirrors are too small, which makes it difficult to the install halogen lamps, the typical heat sources, and the quartz tube constituting the single crystal growth chamber. When the interfocal distance of the spheroid mirrors is greater than 67.0 mm, apparatus downsizing and cost reduction become difficult. Moreover, an interfocal distance of 67.0 mm or greater does not substantially improve the heating performance. The interfocal distance of the spheroid mirrors is therefore preferably in the range of 41.4-67.1 mm. When the interfocal distance is in this range and the minor axis/major axis ratio is 0.90-0.95, the major axes a of the spheroid mirrors is 57.7-80 mm and the minor axes b thereof is 52-76 mm.

Further, when the minor axis/major axis ratio is less than 0.90, the first and second foci and the common focus are too far apart and the shape of the spheroid mirrors becomes like that of a rugby ball, so that the focusing property of the spheroid mirrors of bi-spheroid type becomes high in the optical axis direction but is made uneven in the horizontal plane of the planar heated material including the optical axis. When the minor axis/major axis ratio is greater than 0.95, the spheroid mirrors are nearly spherical and the first and second foci and the common focus are too close, and, single crystal growth becomes impossible because the small spheroid mirrors make it difficult to install the halogen lamps that are the heat sources, and the quartz tube constituting the single crystal growth chamber. The minor axis/major axis ratio is therefore preferably in the range of 0.90-0.95.

Simulation was preformed with regard to the appropriateness of the aforesaid numerical values assuming spheroid mirrors 61, 62 such as shown in FIG. 1. In FIG. 1, 63, 64 are halogen or other infrared lamps. Here, with regard to 8 types of spheroid mirrors having fixed interfocal distances F₁-F₀, F₂- F₀ of 50 mm and varying in minor axis and major axis, the radiation power density and radiation power obtained were checked by simulation for the case of using as the lamps 63, 64 two 650 W lamps having plate filaments and two 650 W lamps having cylindrical filaments. FIG. 2 shows a feed rod 67 and a seed crystal rod 69 both of 4 mm diameter. The radiation power density was the power density (W/mm²) radiated onto a 4 mm vertical region of the heating zone M between the two upper and lower rods 67, 69. And the radiation power was the power (W) radiated onto upper and lower 25 mm regions including the 4 mm region of the heating zone M.

FIGS. 3 to 5 show the results by verifying the appropriateness of the minor axis/major axis ratio 0.90-0.95 using optical software. The 8 types of spheroid mirrors 61, 62 designated from left to right in FIG. 3 as S11, S2, S3, S8, S12, S13, S14 and S15 were successively 0.01 larger in minor axis/major axis ratio in the order shown. In FIGS. 4 and 5, the plots of the values obtained with the plate 650 W lamp are indicated by ▪ and those obtained with the cylindrical 650 W lamp by ● FIG. 4 shows that with both the plate lamp and the cylindrical lamp, the power density first increased gradually with increasing minor axis/major axis ratio but did not change rightward of S8 (minor axis/major axis ratio: 0.92). In contrast, FIG. 5 shows that the power density peaked at S12 (minor axis/major axis ratio; 0;93) with the plate lamp and at S8 (minor axis/major axis ratio: 0.92) with the cylindrical lamp, and decreased gradually on either side of the peaks.

It can be seen from FIG. 4 that the radiation power density at the 4 mm heating zone M did not change for minor axis/major axis ratios of 0.92 and larger. However, FIG. 5 shows that in the region extending 25 mm upward and downward of the 4 mm zone, the radiation power peak was at a minor axis/major axis ratio of 0.92 or 0.93. Since the temperature reached by the 4 mm heating zone M of course increases with increasing radiation power in this region, the final conclusion can be seen to be that with the plate lamp, S12 (minor axis l major axis ratio: 0.93) exhibits the highest heating performance, and with the cylindrical lamp, S8 (minor axis/major axis ratio: 0.92) exhibits the highest heating performance. The heating performance declines when the minor axis/major axis ratio is larger or smaller than these values.

Although an object of the present invention is to enable heating performance of 2,000° C. or higher, a more specific object is to enable heating performance of not lower than 2,060° C., the melting point of ruby (Al₂O₃+1% Cr₂O₃; melting point about 2,060° C.), so as to make it possible to melt and grow ruby single crystal. Therefore, as shown in FIG. 6, simulation of heating performance (radiation power density and radiation power) was performed for use of the S6-S10 and S16 spheroid mirrors, which had nearly ideal minor axis/major axis ratios, and the plate 650 W lamp. The spheroid mirrors grew gradually longer in focal length going from S6 toward S10 and S16. From the simulation results in FIG. 7, it was found that with the spheroid mirrors from S8 rightward the radiation power density exceeded 2.371 and that there was no difference in radiation power density between S10 and S16. The radiation power density and radiation power values of 2.371 and 404.5 are the values actually measured when melting ruby in a real apparatus. In other words, it was found from the simulation of FIG. 6 that heating performance of 2,060° C. or higher can be achieved by using the S8-S10 and S16 spheroid mirrors. High heating efficiency can generally be obtained at low power by downsizing the apparatus while taking the influence of the interfocal distance and minor axis/major axis ratio on heating performance into account; however, heating performance does not change at focal lengths F longer than 33.5 mm, heating performance gradually decreases at focal lengths shorter than 33.5 mm and heating performance decreases sharply when the focal length F becomes shorter than that of the S7 spheroid mirror (focal length: 20.67). Therefore, the spheroid mirrors that enable optimum downsizing of the apparatus while making it possible to achieve a heating performance of 2,060° C. using the plate 650 W lamp are S8-S10.

Next, the optimum value of the heating power (lamp output) will be considered based on the simulation of FIGS. 9 and 10. These figures relate to simulation of change in melt zone power density and temperature reached when the S8 spheroid mirror was used and the rating of a lamp with plate-like filament was varied between 350 W and 950 W in increments of 50 W. As can be seen from the figures, a comparison of the lamps rated 650 W and 950 W shows that the temperature increased by no more than a mere 2.6% despite a power increase of about 46%. The spheroid mirrors are gold plated and, assuming a fixed cooling capacity, the only way to keep the plating layers from peeling is either to increase the mirror area or to hold down the power used. Since the apparatus of the present invention needs to be downsized, a lamp must be selected that can achieve the desired temperature and whose rating is as small as possible. Moreover, regarding lamp service life, it is known that use at 90% or less of the rating markedly extends average service life. Therefore, in the case where the desired temperature is 2,060° C., at which ruby melts, it follows that such lamp rating needs to be 550 W or greater and the upper limit thereof is 750 W at most. With a lamp of 750 W or greater, the temperature reached increases little for the amount of rating increase, while the flow rate of the cooling gas has to be increased, which makes the efficiency still worse. And the desired temperature of 2,060° C. at which ruby melts cannot be achieved at a rating of 550 W or less. However, even at a rating of 550 W, it is completely possible to grow crystal of a material whose melting temperature is around 1,000° C.

### EFFECT OF THE INVENTION

In the aforesaid single-crystal growth apparatus, the interfocal distance between the one and the other foci of the spheroid mirrors is made 41.4-67.0 mm, about half that heretofore, and the minor axis/major axis ratio of the spheroid mirrors is made 0.90-0.95, so that the outputs of the infrared lamps required to achieve the same heating performance becomes only about half that heretofore.

In the present invention, the spheroid mirrors include the internal water-cooling jackets, the ends of the spheroid mirrors in the major axis direction are formed with the heat source insertion holes for inserting the heat sources into the inner space of the spheroid mirrors, and the cooling units are provided for introducing cooling gas for cooling the spheroid mirrors and heat sources from the gap regions inward of the heat source insertion holes into the inner space of the spheroid mirrors at a flow rate of 1.2-2.3 m³/min, so that cooperative action between the water cooling of the spheroid mirrors by the water-cooling jackets and the air cooling of the reflection surfaces of the spheroid mirrors by the air-cooling units enables thorough cooling of the spheroid mirrors, thereby preventing excessive temperature rise of the spheroid mirrors and preventing peeling of the gold plating layers. Further, since excessive temperature rise of the heat sources can be prevented by cooling the heat sources with the cooling gas, it is possible, for example, to appropriately maintain the halogen cycle of halogen lamps to perform stable heating by the halogen lamps, prevent excessive temperature rise of seal regions of molybdenum foil and quartz present at the current feeding sections of the halogen lamps, prevent peeling caused by difference in thermal expansion coefficient between the two, and prevent seal breakdown of the current feeding sections.

### BEST MODE FOR CARRYING OUT THE INVENTION

In the following, embodiments of the single-crystal growth apparatus according to the present invention will be explained with reference to the drawings. FIGS. 11-1 to 11-4 are an overall front view, side view, plan view and rear view of a single-crystal growth apparatus 1 of bi-spheroid type that uses infrared lamps as heat sources. FIGS. 12-1 to 12-3 are an enlarged longitudinal sectional view seen from the front, enlarged side view and enlarged plan view of the heating furnace section in the single-crystal growth apparatus 1 of FIG. 11-1, and FIG. 13 is an enlarged longitudinal sectional view seen from the front of the heating zone in the single-crystal growth apparatus 1 of FIG. 11-1.

The single-crystal growth apparatus 1 is divided broadly into a pedestal section 2, a heating furnace section 3, and a shaft drive section 4. The pedestal section 2 is formed frame-like by a top plate section 2a, a bottom frame section 2b and multiple leg sections 2c, and is provided with carrying handles 2d on the left and right of the top plate section 2a.

The heating furnace section 3 is equipped with a frame cover section 5, a heating furnace support section 6 located inside the frame cover section 5, and a heating furnace 10. The frame cover section 5 is equipped with a top plate section 5a, front doors 5b, 5c openable to the left and right, side panel sections 5d, 5e integral with the front doors 5b, 5c that cover the forward sides of the left and right side surface sections, side panel sections 5f, 5g that cover the rearward sides that are the remaining sections of the left and right side surface sections not covered by the side panel sections 5d, 5e, and a back panel section 5h. The top plate section 5a is provided with an opening 5i through which a later-described upper shaft drive section (7) projects. The front door 5b on the left side is larger than the front door 5c on the right side, and the front door 5b is provided with a peep hole 5j that magnifies and displays the heating zone of the heating furnace 10. Further, the side panel sections 5f, 5g at the left and right reward sides are provided with air inlet ports 5k, 5m for taking in cooling air for air cooling explained later. The back panel section 5h is provided with an exhaust port 5n for exhausting used air passed through a radiator explained later. Further, the heating furnace support section 6 is configured to have a top plate section 6a and a bottom plate section 6b supported by multiple leg sections 6c at prescribed spacing.

The shaft drive section 4 is equipped with an upper shaft drive section 7 and a lower shaft drive section 8. The structures of the upper shaft drive section 7 and lower shaft drive section 8 will be explained later.

The heating furnace 10 includes two symmetrical spheroid mirrors 11, 12 made of brass or the like. The spheroid mirrors 11, 12 have one foci F₁, F₂ and other foci F₀, (see FIG. 12-1) and are joined to face each other so that the one foci F₀ thereof coincide, thereby configuring a heating furnace of bi-spheroid type. The inner surfaces of the spheroid mirrors 11, 12, i.e., their reflection surfaces, are gold plated so as to reflect infrared rays at high reflectance.

Heat sources, e.g., halogen lamps or other type of infrared lamps 13, 14, are fixedly mounted near the one foci F₁, F₂ of the spheroid mirrors 11, 12. A heating zone 15 is located at the coincident other foci F₀ of the spheroid mirrors 11, 12, and a quartz tube 16 is installed vertically to surround the heating zone 15. In this connection, the infrared lamps 13, 14 can be of light-bulb type having a coil-like filament strung in substantially cylindrical shape between two support members inside a bulb-shaped quartz tube or be one having a coil-like filament strung in substantially rectangular shape between two support members inside a substantially cylindrical quartz tube.

The quartz tube 16 partitions an inner space m₁ of the quartz tube 16 off from the remaining inner space m₂ of the spheroid mirrors 11, 12, thereby replacing the inner space m₁ of the quartz tube 16 with an atmosphere favorable for single crystal growth and making this atmosphere easy to maintain. On the other hand, infrared lamps 13, 14 in the inner space m₂ within the spheroid mirrors 11, 12 are helped to be cooled by air-cooling units explained later without affecting the heating zone 15 in the inner space m₁ of the quartz tube 16.

A feed rod 18 fixed to the lower end of an upper crystal drive shaft 17 extending vertically from above and a seed crystal rod 20 fixed to the upper end of a lower crystal drive shaft 19 extending vertically from below are abutted at the heating zone 15. The upper crystal drive shaft 17 and lower crystal drive shaft 19 are airtightly retained on respective retaining members 21, 22 by bearings so as to be rotated by the upper shaft drive section 7 and lower shaft drive section 8.

The upper shaft drive section 7 is equipped with a pair of guide members 23 for guiding vertical movement of the retaining member 21, a main shaft rotation motor 24, a belt 25, a main shaft feed motor 26 and a feed screw 27, and supports the upper crystal drive shaft 17 to be rotatable forward and backward by the main shaft rotation motor 24 and belt 25 and to be vertically movable by the main shaft feed motor 26, feed screw 27 and retaining member 21. Further, the lower shaft drive section 8 is equipped with a pair of guide members 28 for guiding vertical movement of the retaining member 22, a main shaft rotation motor 29 (not visible in the drawings), a belt 30, a main shaft feed motor 31 and a feed screw 32, and supports the feed rod 18 to be rotatable forward and backward by the main shaft rotation motor 29 and belt 30 and to be vertically movable by the main shaft feed motor 31, feed screw 32 and retaining member 22. The upper crystal drive shaft 17 and lower crystal drive shaft 19 retained to be movable vertically either synchronously or so as to have a relative velocity, in accordance with the speeds of the main shaft feed motors 26, 31.

Further, the upper shaft drive section 7 and lower shaft drive section 8 are equipped with height position adjustment means for manually adjusting the height position of the upper crystal drive shaft 17 and lower crystal drive shaft 19 respectively supporting the feed rod 18 and seed crystal rod 20. The illustrated height position adjustment means are equipped with knurled knobs 33, 34 screw-engaged with the feed screws 27, 32, respectively, and the height positions of the retaining members 21, 22, namely, the height positions of the upper crystal drive shaft 17 and lower crystal drive shaft 19, can be coarsely adjusted by the knurled knobs 33, 34. Further, the upper shaft drive section 7 and lower shaft drive section 8 are provided with limit switches 35, 36 and 37, 38 at locations near the movement paths of the retaining members 21, 22, respectively, which upper limit switches 35, 37 detect upper limit points of the retaining members 21, 22 and which lower limit switches 36, 38 detect the lower limit points of the retaining members 21, 22, whereby the retaining members 21, 22 do not move farther upward or downward.

The spheroid mirrors 11, 12 are equipped with annular water-cooling jackets 39, 40 and are cooled by supplying cooling water thereto. Unlike the conventional single-use configuration in which cooling water would be supplied from a water tap, for example, and the cooling water raised in temperature exiting the annular water-cooling jackets 39, 40 would be discarded, the cooling system, which will be explained later, is configured to circulate the cooling water supplied to the annular water-cooling jackets 39, 40 using closed piping inside the single-crystal growth apparatus 1.

Further, the ends of the spheroid mirrors 11, 12 in the major axis direction are formed with infrared lamp insertion holes 41, 42 for inserting the infrared lamps 13, 14 into the inner space m₂ of the spheroid mirrors 11, 12. The infrared lamps 13, 14 are inserted from the infrared lamp insertion holes (hereinafter called insertion holes) 41, 42 into the inner space m₂ of the spheroid mirrors 11, 12, and gaps 43, 44 of inverted groove shape are present between the inner edge of the insertion holes 41, 42 and base sections 13A, 14A of the infrared lamps 13, 14. The gaps 43, 44 are utilized to provide air-cooling units 45, 46 for supplying cooling air for cooling the inner surfaces of the spheroid mirrors 11, 12 and the infrared lamps 13, 14. Air taken in from the air inlet port 5m of the cover frame section 5 is supplied to the air-cooling units 45, 46 by cooling air supply means, e.g., a blower 47 (FIG. 11-4), and the air-cooling units 45, 46 blow the cooling air into the-aforesaid gaps.

The air-cooling units 45, 46 can, as shown in FIGS. 12-2, 12-3 and 14A, be configured to supply cooling gas, e.g., cooling air, to the inverted-groove-shaped gaps 43, 44 through air-cooling sections 45a, 45b, 46a and 46b branching from the gaps 43, 44 on opposite sides of the infrared lamps 13, 14, or, as shown in FIG. 14B, be configured to supply cooling gas, e.g., cooling air, through unitary air-cooling sections 45c, 46c along the inverted-groove-shaped gaps 43, 44.

Further, the middle of the upper and lower ends of the spheroid mirrors 11, 12 in the minor axis direction are formed with loading holes 48 and gaps are formed between the spheroid mirrors 11, 12 and the quartz tube 16 at the loading hole 48 sections. The configuration is such that the cooling air supplied into the inner space m₂ of the spheroid mirrors 11, 12 by the air-cooling units 45, 46 becomes turbulent inside the spheroid mirrors 11, 12, thereby cooling the spheroid mirrors 11, 12 and the infrared lamps 13, 14, and is exhausted through the gaps between the spheroid mirrors 11, 12 and quartz tube 16 at the loading hole 48 sections of the spheroid mirrors 11, 12.

Further, as explained earlier, the cooling water supplied to the annular water-cooling jackets 39, 40 of the spheroid mirrors 11, 12 absorbs heat of the spheroid mirrors 11, 12 and passes through a radiator 49 to circulate within the single-crystal growth apparatus 1 via a closed system, and cooling air is blown onto the radiator 49. Therefore, the cooling water passing through the radiator 49 dissipates heat at the radiator 49 and is once again supplied to the annular water-cooling jackets 39, 40 in a lowered temperature state. Therefore, the spheroid mirrors 11, 12 can be water cooled to the prescribed temperature notwithstanding that the configuration is such that the cooling water is circulated and supplied by a closed system inside the single-crystal growth apparatus 1.

Next, the operation of the single-crystal growth apparatus 1 will be explained. First, the interiors of the spheroid mirrors 11, 12 are water cooled by supplying cooling water to the annular water-cooling jackets 39, 40 of the spheroid mirrors 11, 12 and circulating it through the closed system of the single-crystal growth apparatus 1 so as to dissipate heat at the radiator 49, and the blower 47 is operated so that the air-cooling units 45, 46 blow cooling air jet-like from the gaps 43, 44 of the spheroid mirrors 11, 12 toward the inside of the spheroid mirrors 11, 12 at a flow rate of 1.2-2.3 m³ /min. By this, the infrared lamps 13, 14 and their base sections 13A, 14A are cooled by the blowing of the cooling air and the cooling air supplied to the inner space m₂ of the spheroid mirrors 11, 12 becomes turbulent in the inner space m₂ of the spheroid mirrors 11, 12, thereby air cooling the inner surfaces of the spheroid mirrors 11, 12 and the infrared lamps 13, 14, and air residing in the inner space m₂ of the spheroid mirrors 11, 12 is exhausted from the loading holes 48 for the quartz tube 16 provided at the top and bottom of the spheroid mirrors 11, 12.

Then, after replacing the inner space m₁ of the quartz tube 16 with an inert gas or other appropriate atmospheric gas, the infrared lamps 13, 14 located near the one foci F₁, F₂ of the spheroid mirrors 11, 12 are energized and the infrared rays emitted by infrared lamps 13, 14 are reflected by the spheroid mirrors 11, 12 to be focused on the heating zone 15 located at the other or common focus F₀, thereby performing infrared heating. Owing to the infrared heating, the lower end of the feed rod 18 and the upper end of the seed crystal rod 20 are smoothly brought into contact while being heated and melted, whereby a small-diameter floating zone (hereinafter designated FZ) 50 (omitted in the drawings) is formed at the heating zone 15 between the feed rod 18 and seed crystal rod 20, similarly to in FIG. 17.

Then, the upper crystal drive shaft 17 having the feed rod 18 fastened to its lower end and the lower crystal drive shaft 19 having the seed crystal rod 20 fastened to its upper end are both rotated by the main shaft rotation motors 24, 29 (at, for example, 20-30 rpm) and are moved slowly downward synchronously by the main shaft feed motors 26, 31, whereby the FZ 50 formed at the heating zone 15 between the feed rod 18 and seed crystal rod 20 gradually shifts to the side of the feed rod 18 to grow single crystal. The FZ 50 portion at this time is the same as that in FIG. 17 used to explain the prior art single-crystal growth apparatus. In the apparatus of the present invention, however, the heating zone 65, feed rod 67, solid-liquid interface 67a on the feed rod 67 side, seed crystal rod 69, solid-liquid interface 69a on the seed crystal rod 69 side and, FZ 74 are to be respectively read as the heating zone 15, feed rod 18, solid-liquid interface 18a on the feed rod 18 side, seed crystal rod 20, solid-liquid interface 20a on the seed crystal rod 20 side, and FZ 50.

At this time, the temperatures of the spheroid mirrors 11, 12 and infrared lamps 13, 14 are increased by radiant heat from the infrared lamps 13, 14 and the FZ 50 and heat transfer by air residing and circulating inside the spheroid mirrors 11, 12, but the temperature of the spheroid mirrors 11, 12 does not rise excessively because, as explained earlier, the water cooling of the spheroid mirrors 11, 12 by the cooling water passing through the annular water-cooling jackets 39, 40 and the air cooling by the cooling air supplied from the air-cooling units 45, 46 by the blower 47 cool the spheroid mirrors 11, 12, and, therefore, no peeling of the gold plating layer occurs owing to the difference in thermal expansion coefficient between the material (e.g., brass) constituting the spheroid mirrors 11, 12 and the gold plating layer on the inner surfaces thereof. In addition, the temperature of the infrared lamps 13, 14 is appropriate because the infrared lamps 13, 14 and their base sections 13A, 14A are cooled by the cooling air supplied from the air-cooling units 45, 46 and the turbulence of the cooling air arising inside the spheroid mirrors 11, 12, so that the halogen cycle is maintained to enable efficient and stable infrared ray radiation, while the temperature of the seal regions of molybdenum foil and quartz at the current feeding sections is maintained at not higher than 350° C., so that no seal breakdown of the current feeding sections occurs owing to the difference in thermal expansion coefficient between the molybdenum foil and quartz.

In this connection, in the case where the water cooling and air cooling is impaired because of, for example, failure of the blower 47 or the cooling water circulation system, the temperature of the spheroid mirrors 11, 12 rises because the spheroid mirrors 11, 12, infrared lamps 13, 14 and their base sections 13A, 14A cannot be properly cooled even if water cooling by the annular water-cooling jackets 39, 40 of the spheroid mirrors 11, 12 and air cooling by the air-cooling units 45, 46 are conducted; however, if temperature rise detection means, e.g., thermostats 51, 51 are installed above the spheroid mirrors 11, 12, the thermostats 51, 51 will operate to cut off the supply of current to the infrared lamps 13, 14 during the overheated state of the spheroid mirrors 11, 12, thereby terminating the heating.

It is noted that the foregoing embodiment was explained with respect to a particular embodiment of the present invention, and the present invention is in no way limited to this embodiment but is capable of various modifications.

For example, the foregoing embodiment was explained with respect to the case of cooling air being introduced inside the spheroid mirrors 11, 12 by the air-cooling units 45, 46 from the gaps 43, 44 between the insertion holes 41, 42 of the spheroid mirrors 11, 12 and the infrared lamps 13, 14 and being exhausted to the exterior from gaps between the spheroid mirrors 11, 12 and the quartz tube 16 at the loading hole 48 sections; however, oppositely from this, it is possible to introduce the cooling air inside the spheroid mirrors 11, 12 from the gaps between the spheroid mirrors 11, 12 and quartz tube 16 at the loading hole 48 sections and exhaust it to the exterior from the gaps 43, 44 between the insertion holes 41, 42 of the spheroid mirrors 11, 12 and the infrared lamps 13, 14. Otherwise, it is possible to form cooling air vents in the reflective surfaces of the spheroid mirrors 11 12, introduce the cooling air inside the spheroid mirrors 11, 12 from these air vents, and exhaust it to the exterior from the gaps 43, 44 between the spheroid mirrors 11, 12 and the infrared lamps 13, 14 at the insertion holes 41, 42 and/or the gaps between the spheroid mirrors 11, 12 and the quartz tube 16 at the loading hole 48 sections.

Further, although, as was indicated regarding the foregoing embodiment, it is advantageous for enabling further price reduction of the apparatus to adopt knurled knobs or other such manual adjustment means instead of the motor driven system of the prior art apparatus as the drive means for fine adjustment of the height position of the upper crystal drive shaft 17 and lower crystal drive shaft 19, change to a motor driven system is possible.

Although the present invention manifests particularly notable effect in a single-crystal growth apparatus equipped with a so-called heating furnace of bi-spheroid type combining the two spheroid mirrors 11, 12 indicated in the embodiment, it can instead be implemented in a single-crystal growth apparatus of tetra-spheroid type.

Further, the cooling water supplied to the annular water-cooling jackets 39, 40 in a circulating manner can be cooled using electronic cooling elements or the like. In this case, the cooling effect of the annular water-cooling jackets 39, 40 is further enhanced.

### EXAMPLE 1

Next, an example of the present invention will be explained.

(Single-crystal growth apparatus configuration)
Spheroid mirrors 11, 12: Material=brass, Focal length F=25 mm, Major axis a=65 mm, Minor axis b=60 mm, Minor axis/Major axis ratio b/a=0.92, Inner surface gold plating layer
Heat sources 13, 14: Halogen lamps, 650 W
Quartz tube 16: Outside diameter φ 35 mm, Inside diameter φ 31 mm, Length 185 mm
Feed rod 18: φ 4-6 mm
Seed crystal rod 20: φ 4-6 mm
Main shaft rotation motors 24, 29: Variable speed motors
Main shaft feed motors 26, 31: Variable speed motors
Knurled knobs 33, 34: Coarse adjustment range±15 mm
Annular water-cooling jackets 39, 40: Cooling water flow rate=3-5 liters/min
Heat source insertion holes 41, 42: Width 55 mm×Length 35 mm
Gaps 43, 44: Width 10 mm×Length 11.5 mm (at center of width)
Air-cooling units 45, 46: Introduce cooling air from gaps on both sides of heat source,
   Cooling air flow rate=1.3-2.3 m³/min
Blower 47: Single phase, 100 V, 0.8 A
FZ 50: Center region diameter φ 5 mm, Height 6 mm (when feed rod, crystal diameter φ 6 mm)
   Overall apparatus dimensions (not including handles):

In case of crystal growth length of 50 mm; Width 650 mm×Height 915 mm×Depth 620 mm

In case of crystal growth length of 150 mm: Width 650 mm×Height 1,400 mm×Depth 620 mm Power requirement: 100 V, 15 A

When the single-crystal growth apparatus of the aforesaid configuration was used and heating by the infrared lamps 13, 14 was conducted concurrently with water cooling and air cooling of the spheroid mirrors 11, 12 and air cooling of the infrared lamps 13, 14, the FZ 50 was favorably formed at the heating zone 15 and it was possible to grow single crystal of aluminum oxide, lanthanum (strontium) manganate and other,macro-magnetoresistive manganese oxides, copper oxide high-temperature superconductors, lanthanum nickelate, nickel oxide, strontium vanadate, borocarbides, sodium colbaltate, aquamarine, peridot, spinel, ruby, pyrochlore, iridium ferrate, strontium titanate, lanthanum aluminate, lithium niobate, calcium fluoride, lanthanum (strontium) gallium oxide, silicate, quartz, strontium ruthenate, lead chromate and the like. All specimens were confirmed by X-ray powder diffraction testing to be monolayer and to have the desired compositions were obtained, and by X-ray single-crystal diffraction to be single crystal. The copper oxide high-temperature semiconductors and the borocarbide and strontium ruthenate superconductors exhibited the reported superconductivity transition temperatures. The other insulating materials exhibited the reported colors, and it was verified that the single-crystal growth apparatus of the present invention has the same capabilities as earlier floating zone type single-crystal growth apparatus.

Next, specific examples of the single crystal growth method using the single-crystal growth apparatus of the present invention will be explained.

### (Example 1) Aluminum oxide (Al₂O₃+1% Cr₂O₃): ruby

99.9% pure Al₂O₃ and Cr₂O₃ powders were weighed out and mixed in an agate mortar to obtain the desired composition ratio and the mixed powder was placed in a rubber tube and pressed into a φ 4 mm diameter rod shape under hydrostatic pressure of 3,000 atmospheres to shape a specimen rod that was sintered for 6 hours at 1,300° C. in air. The sintered specimen was mounted in the singlecrystal growth apparatus of the present invention and the temperature of the feed rod was raised in air by increasing the voltage of the halogen lamps (650 W×2). Melting of the starting material began when the halogen lamps reached 94 V, and growth was conducted at 98 V and a feed rod movement speed of 10 mm/hr. In this manner, single crystal of ruby could be grown. Since the melting point of ruby is 2,060° C., it could be concluded that the single-crystal growth apparatus of the present invention is capable of temperature increase up to 2,000° C.

### (Example 2) Lanthanum (strontium) manganate La_{0.85}Sr_{0.15}MnO₃

99.9% pure La₂O₃, SrCO₃, and Mn powders were measured out and mixed in an agate mortar to obtain the desired composition ratio and pre-fired for 12 hours at 900° C. in air, whereafter the obtained material was pulverized, remixed, and sintered at 1,400° C. in air. The sintered La_{0.85}Sr_{0.15}MnO₃ powder was placed in a rubber tube and pressed into a φ 4 mm diameter rod shape under hydrostatic pressure of 3,000 atmospheres. The shaped specimen rod was sintered for 6 hours at 1,400° C. in air. The sintered feed rod was mounted in the single-crystal growth apparatus of the present invention and the temperature of the feed rod was raised in air by increasing the voltage of the halogen lamps (650 W×2). Melting of the starting material began when the halogen lamps reached 74 V and growth was conducted at 78 V. The feed rod movement speed was 8 mm/hr. The single crystal obtained was confirmed by X-ray powder diffraction and X-ray single-crystal diffraction testing to be monolayer single crystal. Using a SQUID flux meter, it was possible to confirm that the ferromagnetic transition temperature was also the same as reported. In this manner, single crystal of lanthanum (strontium) manganate La_{0.85}Sr_{0.15}MnO₃ could be grown.

### (Example 3) Strontium ruthenate Sr₂RuO₄

99.9% pure strontium ruthenate powder and ruthenium dioxide powder were mixed to obtain the desired composition ratio and pre-fired at 900° C. in air, whereafter the powder was placed in a rubber tube and pressed under hydrostatic pressure of 3,000 atmospheres to form a φ 4 mm diameter rod shape that was sintered for 6 hours at 1,200° C. in air. The sintered feed rod was mounted in the single-crystal growth apparatus of the present invention and the temperature of the feed rod was raised in air by increasing the voltage of the halogen lamps (650 W×2). Melting of the starting material began when the halogen lamps reached 93 V and growth was conducted at 95 V. The feed rod movement speed was 30 mm/hr. The single crystal obtained was confirmed by X-ray powder diffraction and X-ray single-crystal diffraction testing to be monolayer single crystal.

In none of the foregoing Examples was there observed peeling of the gold plating layers of the spheroid mirrors 11, 12 or swelling thereof signifying imminent peeling. Moreover, the current feeding sections of the infrared lamps 13, 14 were maintained at or below 350° C. and no seal breakdown caused by peeling of quartz and molybdenum foil was observed at the seal regions of quartz and molybdenum foil. In contrast, in the case of a comparative example which was not provided with the air-cooling units 45, 46 for supplying cooling air inside the spheroid mirrors at a flow rate of 1.2-2.3 m³/min, and in which, as in the prior art, the spheroid mirrors were water cooled and the flow rate of cooling air supplied into the spheroid mirrors for cooling the halogen lamps was set at 5-10 liters/min, the inner surface temperature of the spheroid mirrors 11, 12 exceeded 100° C., so that the gold plating layer peeled or swelled to pose a risk of peeling, Further, temperature of the current feeding sections of the infrared lamps 13, 14 rose to or higher than 350° C., so that the infrared lamps broke owing to seal breakdown leakage from the seal regions of molybdenum and quartz.

### BRIEF EXPLANATION OF THE DRAWINGS

FIG. 1 is a cross-sectional view of spheroid mirrors of bi-spheroid type used in the single-crystal growth apparatus according to the present invention.

FIG. 2 is a side view of a feed rod and a seed crystal rod.

FIG. 3 is a set of tables showing results of simulation for verifying the appropriateness of minor axis/major axis ratio.

FIG, 4 is a graph plotted with results of simulation for verifying the appropriateness of minor axis/major axis ratio.

FIG. 5 is a graph plotted with results of simulation for verifying the appropriateness of minor axis/major axis ratio.

FIG. 6 is a set of tables showing results of simulation for verifying the appropriateness of focal length.

FIG. 7 is a graph plotted with results of simulation for verifying the appropriateness of focal length.

FIG. 8 is a graph plotted with results of simulation for verifying the appropriateness of focal length.

FIG. 9 is set of tables showing results of simulation for verifying the appropriateness of heat source power.

FIG. 10 is a graph plotted with results of simulation for verifying the appropriateness of heat source power.

FIG. 11-1 is a front view of a single-crystal growth apparatus that is an embodiment of the present invention.

FIG. 11-2 is a right side view of the single-crystal growth apparatus of FIG. 11-1.

FIG. 11-3 is a plan view of the single-crystal growth apparatus of FIG. 11-1.

FIG. 11-4 is a rear view of the single-crystal growth apparatus of FIG. 11-1.

FIG. 12-1 is a longitudinal sectional view seen from the front of the single-crystal growth apparatus of the present invention shown in FIG. 11- 1.

FIG. 12-2 is a left side view of the heating furnace shown in FIG. 12-1.

FIG. 12-3 is a plan view of the heating furnace shown in FIG. 12-1.

FIG. 13 is an enlarged longitudinal sectional view seen from the front of the heating zone in the single-crystal growth apparatus of FIG. 11-1.

FIG. 14A is a side view of the cooling air blowing state of the air-cooling units in the single-crystal growth apparatus of the present invention.

FIG. 14B is a side view of another example of the cooling air blowing state of the air-cooling units in the single-crystal growth apparatus of the present invention.

FIG. 15 is a longitudinal sectional view seen from the front of a conventional single-crystal growth apparatus.

FIG. 16 is a cross-sectional view along line A-A of the single-crystal growth apparatus of FIG. 15.

FIG. 17 is an enlarged front view of the heating zone in the single-crystal growth apparatus of FIG. 15.

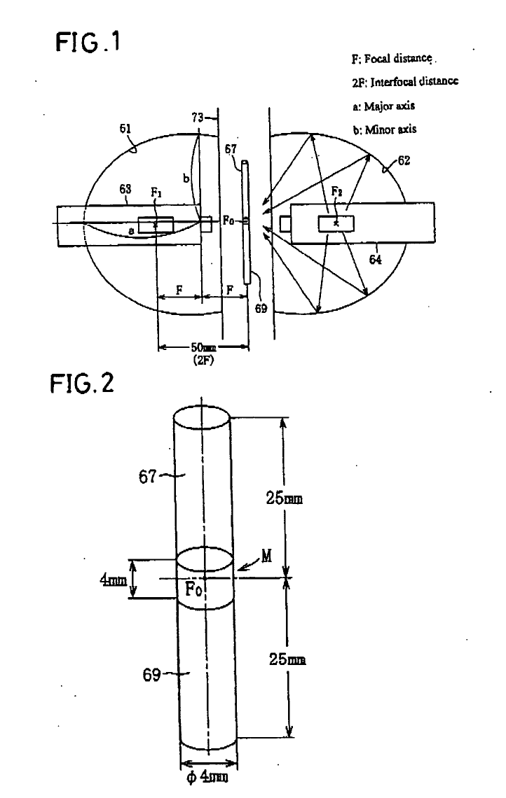

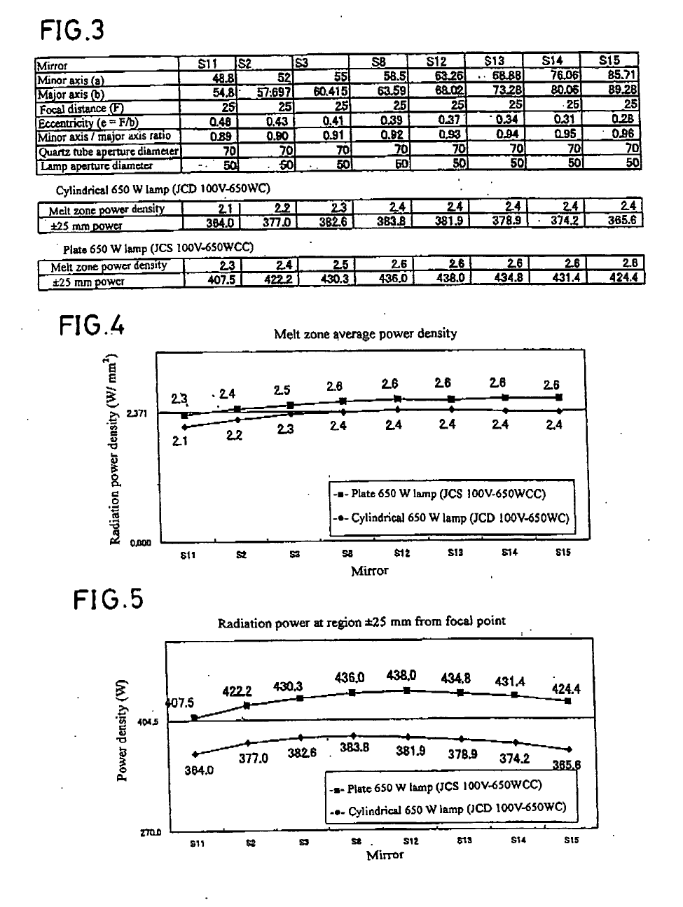

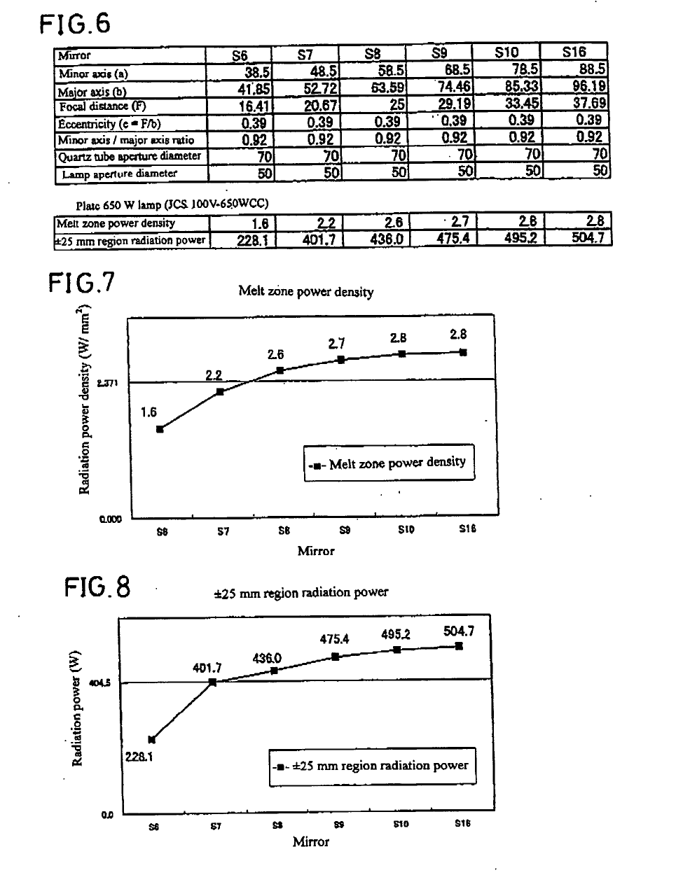

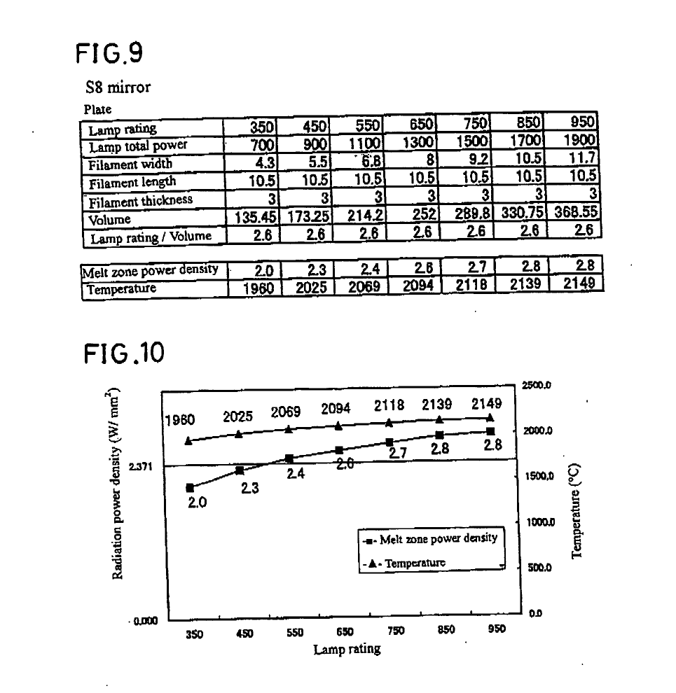

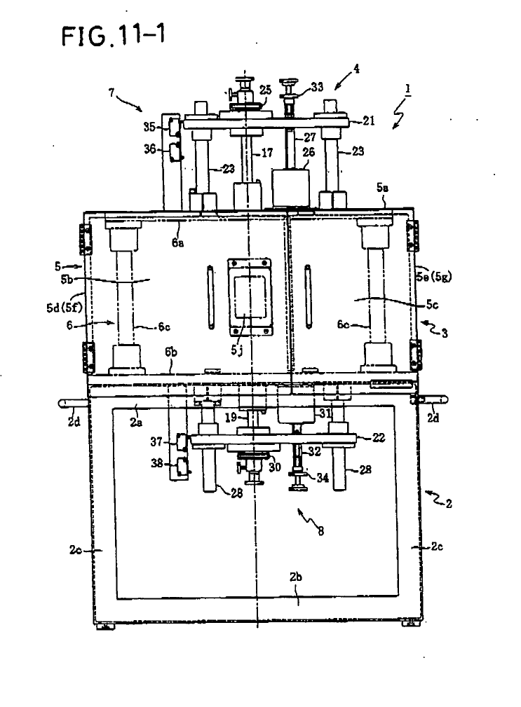

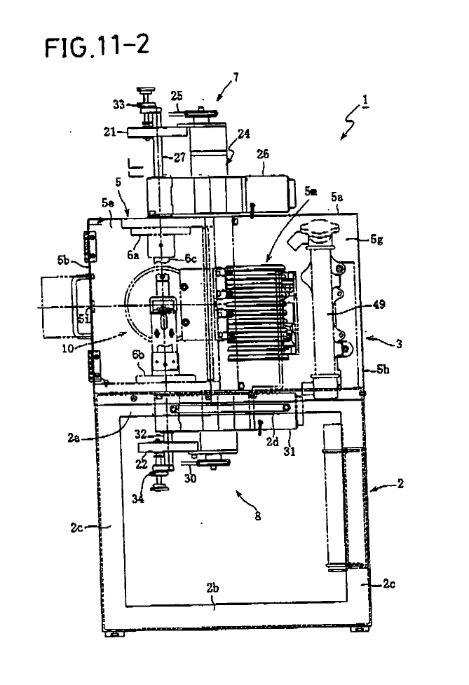

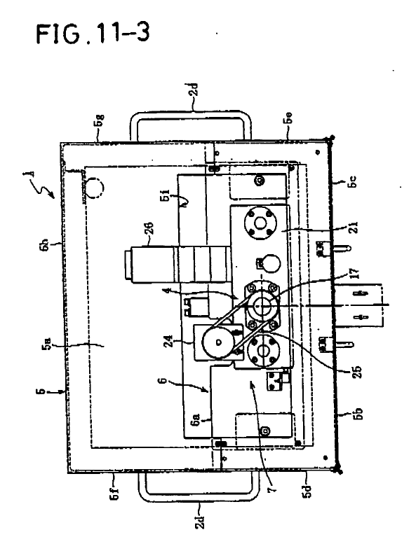

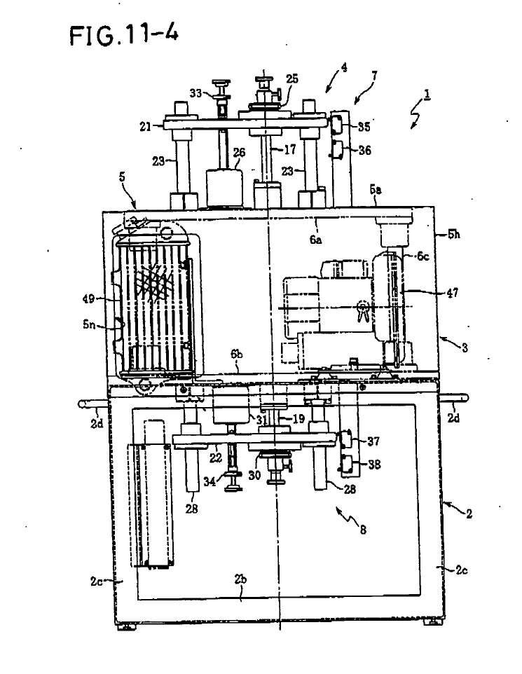

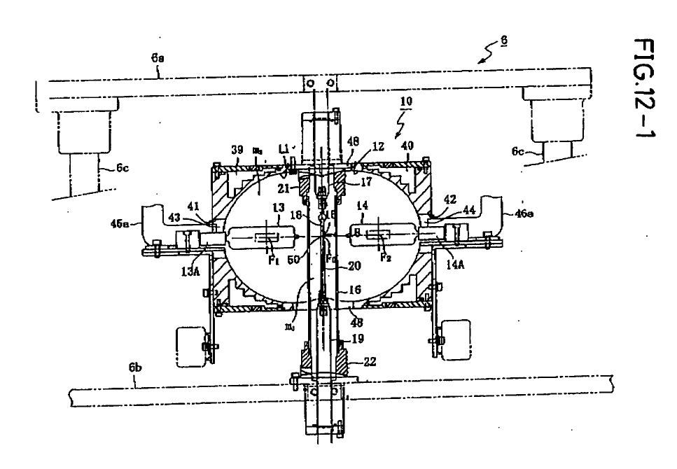

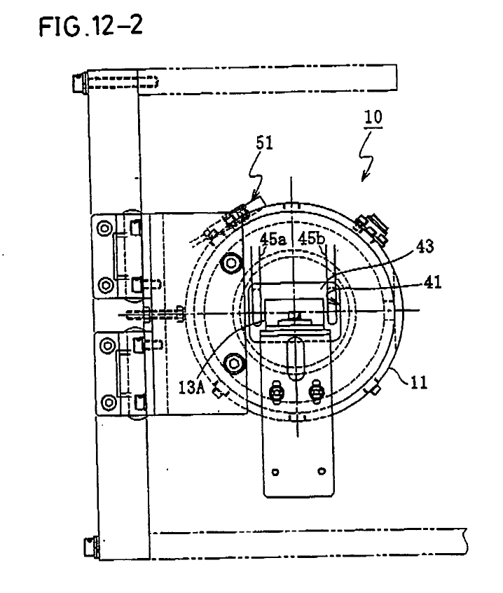

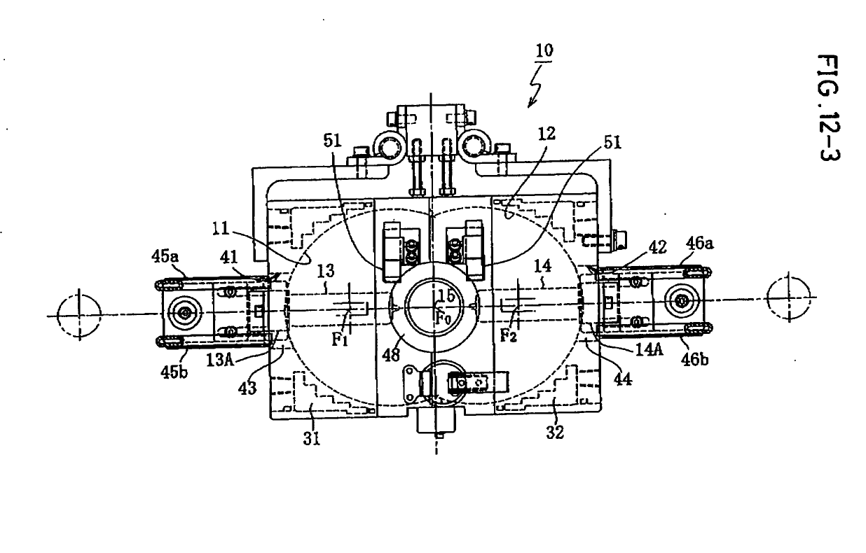

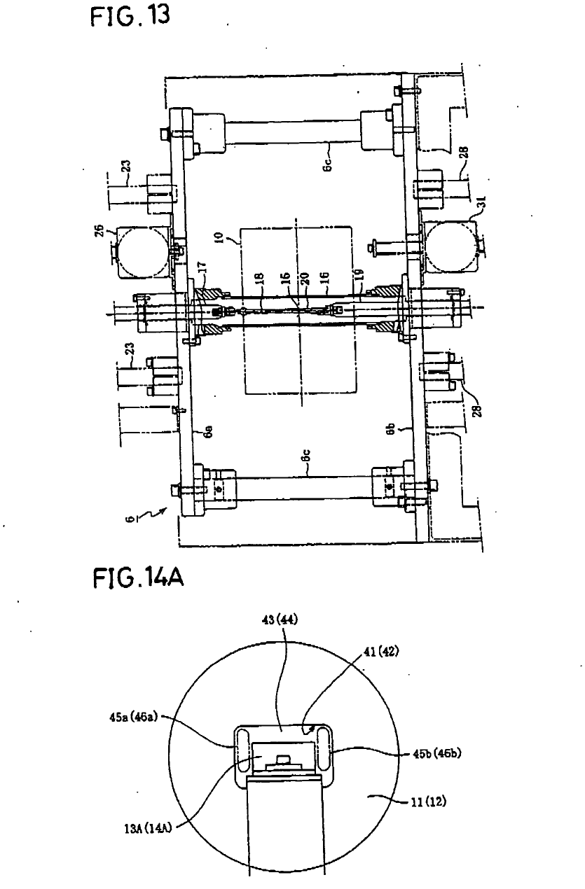

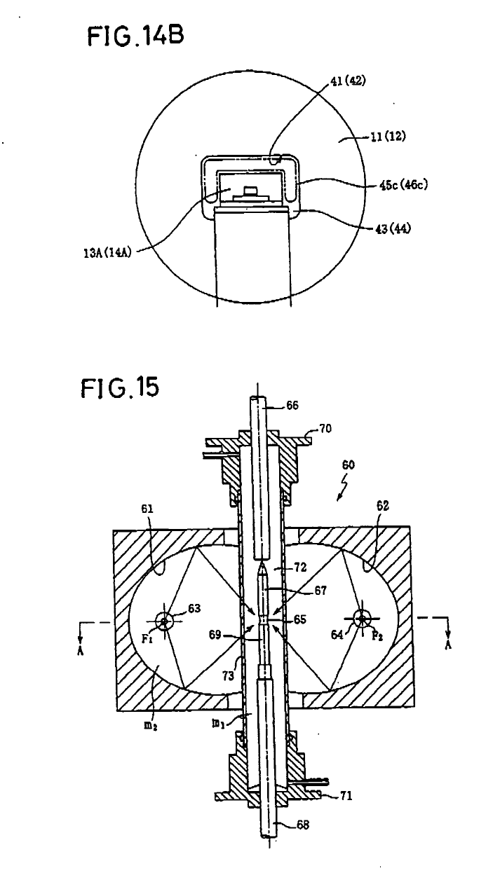

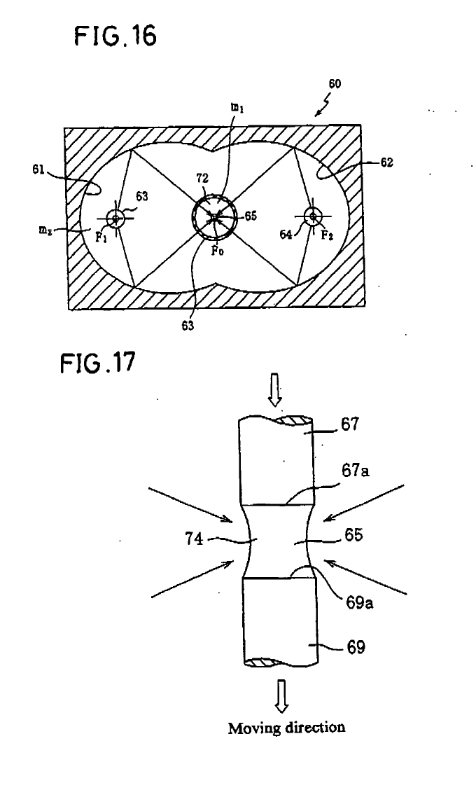

1. A single-crystal growth apparatus which comprises spheroid mirrors, heat sources located at the one foci of the spheroid mirrors, a feed rod and a seed crystal rod located at the other foci of the spheroid mirrors, a quartz tube surrounding the feed rod and seed crystal rod, and shaft drive means for rotating and vertically moving crystal drive shafts respectively supporting the feed rod and seed crystal rod, and in which infrared rays of the heat sources are reflected by the spheroid mirrors to irradiate the feed rod and seed crystal rod located at the other foci, thereby growing single crystal,
which single-crystal growth apparatus is characterized in that the interfocal distance of the one and other foci is made 41.4-67.0 mm and the minor axis/major axis ratio of the spheroid mirrors is made 0.90-0.95.

2. The single-crystal growth apparatus set out in claim 1, characterized in that the major axes of the spheroid mirrors are set to 57.7-80 mm, the minor axes to 52-76 mm, and the total power of the heat sources to 1,100-1,500 W, thereby making it possible to achieve heating performance of 2,000° C.

3. The single-crystal growth apparatus set out in claim 2, characterized in that the spheroid mirrors are of the bi-spheroid type and the total power of the heat sources is set to 1,100-1,500 W, thereby making it possible to achieve heating performance of 2,000° C.

4. The single-crystal growth apparatus set out in claim 3, characterized in that
the spheroid mirrors include internal water-cooling jackets,
the ends of the spheroid mirrors in the major axis direction are formed with beat source insertion holes for inserting the heat sources into the inner space of the spheroid mirrors, and air-cooling units are provided for introducing cooling gas for cooling the spheroid mirrors and heat sources from gap regions inward of the heat source insertion holes into the inner space of the spheroid mirrors at a flow rate of 1.2-2.3 m³/min.

5. The single-crystal growth apparatus set out in claim 4, characterized in that it is configured so that the flow of the cooling gas introduced into the spheroid mirrors from the air-cooling units becomes turbulent in the inner space of the spheroid mirrors to cool the inner surfaces of the spheroid mirrors and the heat sources located in the inner space of the spheroid mirrors.

6. The single-crystal growth apparatus set out in claim 4, characterized in that it comprises a cooling water self-circulation-type heat exhaust system that has a path through which cooling water supplied to the water cooling jackets of the spheroid mirrors circulates via a radiator and dissipates the temperature of the cooling water by supplying cooling air to the radiator.
